(19) United States
(12) Patent Application Publication
(10) Pub. No.: US 2019/0362992 A1
(43) Pub. Date: Nov. 28, 2019

(54) HEAT TREATMENT APPARATUS, HEAT TREATMENT METHOD, AND METHOD FOR MANUFACTURING SEMICONDUCTOR DEVICE

(71) Applicant: Mitsubishi Electric Corporation, Chiyoda-ku, Tokyo (JP)

(72) Inventors: Takeshi MONODANE, Tokyo (JP); Yusuke KAWASE, Tokyo (JP); Haruhiko MINAMITAKE, Tokyo (JP); Hiroaki TATSUMI, Tokyo (JP); Kazunori KANADA, Fukuoka (JP)

(73) Assignee: Mitsubishi Electric Corporation, Chiyoda-ku, Tokyo (JP)

(21) Appl. No.: 16/477,543

(22) PCT Filed: Jan. 18, 2018
(86) PCT No.: PCT/JP2018/001452

§ 371 Date: Jul. 12, 2019

(30) Foreign Application Priority Data
Feb. 2, 2017 (JP) 2017-017665

(51) Int. Cl. H01L 21/67; C21D 1/34; H01L 21/268; H01L 21/66; B23K 26/062

(52) U.S. Cl. CPC H01L 21/67115; C21D 1/34; B23K 26/062; H01L 22/12; H01L 21/268

(57) ABSTRACT

A heat treatment apparatus includes a laser oscillation unit, a stage, an optical system, and a moving unit. The laser oscillation unit oscillates laser light. The stage holds an irradiation target to be irradiated with the laser light. The optical system guides the laser light to the irradiation target. The moving unit relatively changes the positional relationship between the optical system and the irradiation target. Furthermore, the heat treatment apparatus includes a detection unit and a determination unit. The detection unit detects the power of first reflected light that is the laser light reflected from the surface of the irradiation target. On the basis of a detection value of the power of the first reflected light detected by the detection unit, the determination unit determines the presence or absence of a change in the surface temperature of an area irradiated with the laser light on the irradiation target.

### FIELD

The present invention relates to a heat treatment apparatus and treatment method for irradiating an irradiation target with laser light for heat treatment, and a method for manufacturing a semiconductor device.

### BACKGROUND

A process for manufacturing a semiconductor device involves, in some case, heat treatment of a semiconductor substrate to a desired depth. For laser annealing that involves irradiating a semiconductor substrate with a laser to perform activation annealing on a silicon wafer, an end-point temperature is important. It is thus important to measure the temperature state of a laser-irradiated portion in real time.

In Patent Literature 1, a portion of an irradiation target for irradiation with an annealing laser beam is irradiated with a reference laser. The intensity of the reference light reflected from the surface of the irradiation target is measured to thereby detect the heated state of the surface of the irradiation target.

Furthermore, Patent Literature 1 discloses referring to the temperature state of the laser-irradiated portion by detecting the intensity of black-body radiation light from a specific position on the surface of the irradiation target in a beam spot of the annealing laser beam.

### CITATION LIST

### Patent Literature

Patent Literature 1: Japanese Patent No. 5590925

### SUMMARY

### Technical Problem

Unfortunately, the technique disclosed in Patent Literature 1 poses a problem of requiring the reference laser in addition to the laser-annealing laser, thereby making the configuration of an apparatus complicated. In addition, the temperature of the laser-irradiated portion is obtained on the basis of the intensity of black-body radiation light with low accuracy. For the laser-irradiated portion having a small area a width of, for example, approximately 1 mm or less, the measurement itself in such a small area is difficult.

The present invention has been made in view of the above, and has as its object to obtain a heat treatment apparatus simply configured to be capable of detecting the temperature state of a laser-irradiated portion with high accuracy.

### Solution to Problem

In order to solve the above-described problems and to achieve the object, the present invention provides a heat treatment apparatus comprising: a laser oscillation unit to oscillate laser light; a stage to hold an irradiation target to be irradiated with the laser light; an optical system to guide the laser light oscillated by the laser oscillation unit to the irradiation target; and a moving unit to relatively change a positional relationship between the optical system and the irradiation target. The heat treatment apparatus further comprises: a detection unit to detect power of first reflected light that is the laser light reflected from a surface of the irradiation target; and a determination unit to, on a basis of a detection value of the power of the first reflected light detected by the detection unit, determine presence or absence of a change in a surface temperature of an area irradiated with the laser light on the irradiation target.

### Advantageous Effects of Invention

According to the present invention, it is possible to achieve an effect of obtaining a heat treatment apparatus simply configured to be capable of detecting the temperature state of the laser-irradiated portion with high accuracy.

### BRIEF DESCRIPTION OF DRAWINGS

FIG. 1 is a schematic diagram illustrating the configuration of a heat treatment apparatus according to a first embodiment of the present invention.

FIG. 2 is a plan view illustrating a main part of the configuration of the heat treatment apparatus according to the first embodiment of the present invention.

FIG. 3 is a schematic diagram illustrating a reflected state of laser light at an irradiation target in the heat treatment apparatus according to the first embodiment of the present invention.

FIG. 4 is a schematic diagram illustrating a reflected state of laser light at a reflecting mirror in the heat treatment apparatus according to the first embodiment of the present invention.

FIG. 5 is a diagram illustrating an example of the hardware configuration of a processing circuit according to the first embodiment of the present invention.

FIG. 6 is a characteristic diagram illustrating a relationship between the relative reflectance of laser light and the surface temperature of a silicon wafer that is an irradiation target in the first embodiment of the present invention.

FIG. 7 is a flowchart illustrating a procedure of a heat treatment operation of the heat treatment apparatus according to the first embodiment of the present invention.

FIG. 8 is a schematic diagram illustrating the configuration of a heat treatment apparatus according to a second embodiment of the present invention.

FIG. 9 is a flowchart illustrating a procedure of a heat treatment operation of the heat treatment apparatus according to the second embodiment of the present invention.

FIG. 10 is a schematic diagram illustrating the configuration of a heat treatment apparatus according to a third embodiment of the present invention.

FIG. 11 is a schematic diagram illustrating the configuration of a heat treatment apparatus according to a fourth embodiment of the present invention.

FIG. 12 is a plan view illustrating a main part of the configuration of the heat treatment apparatus according to the fourth embodiment of the present invention.

FIG. 13 is a flowchart illustrating a procedure of a method for manufacturing a semiconductor device by use of the heat treatment apparatus according to the fourth embodiment of the present invention.

### DESCRIPTION OF EMBODIMENTS

Hereinafter, heat treatment apparatuses, heat treatment methods, and a method for manufacturing a semiconductor device, according to embodiments of the present invention, will be described in detail with reference to the drawings. It should be noted that the present invention is not limited to the embodiments.

### First Embodiment

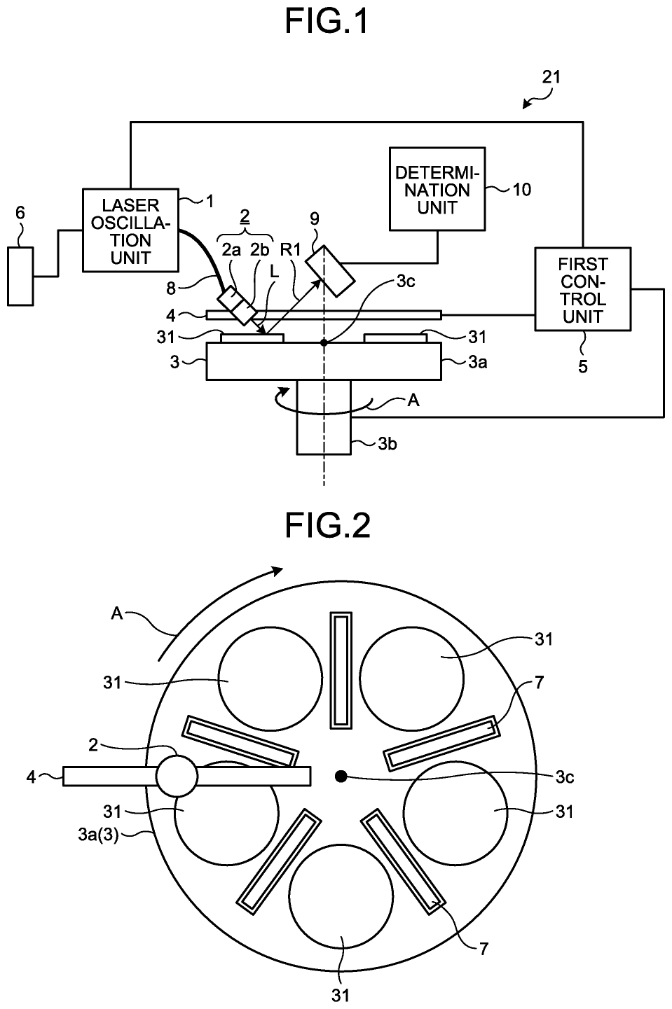

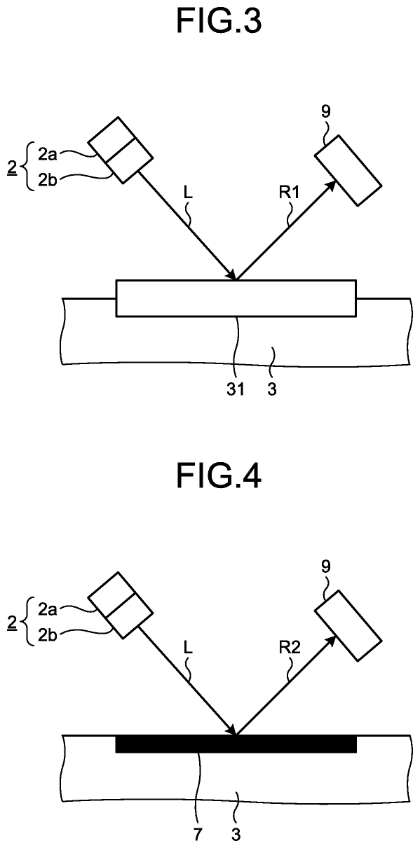

FIG. 1 is a schematic diagram illustrating the configuration of a heat treatment apparatus 21 according to a first embodiment of the present invention. FIG. 2 is a plan view illustrating a main part of the configuration of the heat treatment apparatus 21 according to the first embodiment of the present invention. FIG. 2 illustrates the peripheral part of a turntable 3 of the heat treatment apparatus 21. FIG. 3 is a schematic diagram illustrating a reflected state of laser light L at an irradiation target 31 in the heat treatment apparatus 21 according to the first embodiment of the present invention. FIG. 4 is a schematic diagram illustrating a reflected state of the laser light L at a reflecting mirror 7 of the heat treatment apparatus 21 according to the first embodiment of the present invention.

The heat treatment apparatus 21 according to the first embodiment is an apparatus having the function of a laser annealing apparatus capable of performing laser annealing on the irradiation target 31. Laser annealing refers to heat treatment for achieving a desired characteristic of an irradiation target by changing the crystal arrangement of the irradiation target with heat. It should be noted that the heat treatment apparatus 21 according to the first embodiment can also be applied to overall heat treatment using a laser, in addition to laser annealing. The heat treatment apparatus 21 according to the first embodiment includes a laser oscillation unit 1, an optical system 2, the turntable 3, an optical system moving unit 4, a first control unit 5, a laser output measuring unit 6, the reflecting mirror 7, an optical fiber 8, a detection unit 9, and a determination unit 10.

The laser oscillation unit 1 oscillates the laser light L to be applied to the irradiation target 31. One or more optical systems 2 are connected to the laser oscillation unit 1 via the optical fiber 8. The laser light L oscillated by the laser oscillation unit 1 is transmitted to the optical system 2 via the optical fiber 8. A fiber transmission type laser diode (LD) laser can be used as the laser oscillation unit 1.

The optical system 2 irradiates an irradiation surface of the irradiation target 31 and the reflecting mirror 7 with the laser light L oscillated by the laser oscillation unit 1. As illustrated in FIGS. 1 and 3, the optical system 2 includes a collimation lens 2a and an objective lens 2b. The collimation lens 2a and the objective lens 2b of the optical system 2 collect the laser light L oscillated by the laser oscillation unit 1 and irradiates the irradiation target 31 and the reflecting mirror 7 with the collected laser light L. The collimation lens 2a changes the laser light L oscillated by the laser oscillation unit 1 into parallel light, and guides the parallel light to the objective lens 2b. The objective lens 2b is a condenser lens for collecting the laser light L guided by the collimation lens 2a, and guiding the collected laser light onto the irradiation surface of the irradiation target 31. The objective lens 2b serves as an irradiation port for the laser light L in the optical system 2.

It is possible to simplify the configuration of the optical system 2 by using the fiber transmission type LD laser as the laser oscillation unit 1 as described above. In addition, the optical system 2 and the laser oscillation unit 1 are connected to each other by the flexible optical fiber 8, so that the heat treatment apparatus 21 provides a high degree of freedom for a relative positional relationship between the optical system 2 and the laser oscillation unit 1. Thus, the position of the optical system 2 can be freely set, and the optical system 2 can be easily moved. The heat treatment apparatus 21 is designed such that laser light L oscillated by the laser oscillation unit 1 is transmitted to the optical system 2 through the optical fiber 8, the laser light L is collected by the collimation lens 2a and the objective lens 2b of the optical system 2, and is applied to the irradiation target 31.

It should be noted that in addition to the fiber transmission type LD laser, any of a solid-state laser, a gas laser, a fiber laser, and a semiconductor laser can also be used as the laser oscillation unit 1. However, when the laser oscillation unit 1 is a laser other than the fiber transmission type laser, it is necessary to provide the optical system 2 appropriate for each laser.

Furthermore, a method for laser oscillation is not limited. A laser using any oscillation method can be applied regardless of whether the laser is a continuous oscillation type laser or a pulse oscillation type laser. In the case where the laser oscillation unit 1 is a laser other than the fiber transmission type laser, an optical path does not change depending on the distance from the laser oscillation unit 1 to an irradiation position of laser light. As a result, the configuration of the optical system 2 becomes simpler than the above-described configuration.

Moreover, although the first embodiment is described as to the case of the single laser oscillation unit 1, the number of the laser oscillation units 1 is not limited to one. That is, the heat treatment apparatus 21 may be provided with two or more laser oscillation units 1. When the two or more laser oscillation units 1 are provided, the optical fiber 8 and the optical system 2 are also provided for each of the laser oscillation units 1.

The turntable 3 has both a function of a holding unit that holds the irradiation target 31 and a function of a moving unit that relatively changes a positional relationship between the optical system 2 and the irradiation target 31. The turntable 3 is disposed below the optical system 2 in such a way as to face the irradiation port of the optical system 2. The turntable 3 includes a base 3a and a support shaft 3b. The base 3a of the turntable 3 has a disk shape as illustrated in FIGS. 1 and 2. The base 3a and the support shaft 3b of the turntable 3 are integrally fixed to each other. The support shaft 3b is rotationally driven by a rotary drive unit including a motor (not illustrated). As the support shaft 3b rotates in a direction of an arrow A around an axis perpendicular to an in-plane center 3c of the base 3a, the base 3a also rotates in the circumferential direction of the base 3a in synchronization with the support shaft 3b.

One or more irradiation targets 31 to be annealed are held on the upper surface of the base 3a. In the first embodiment, the base 3a is capable of holding five irradiation targets 31 annularly arranged on its upper surface. A method for fixing the irradiation target 31 on the base 3a is not particularly limited. Thus, it is possible to employ any method such as a method for fitting the irradiation target 31 into a recess provided on the upper surface of the base 3a in conformation to the shape of the irradiation target 31, or a method for sucking the irradiation target 31 into the inside of the base 3a. In addition, a plurality of the reflecting mirrors 7 is held on the upper surface of the base 3a.

The irradiation target 31 is an object to be subjected to laser annealing. Used in the first embodiment is a silicon wafer made of single-crystal silicon subjected to ion implantation of impurities to a depth of 1 μm to 50 μm below the surface. It should be noted that the irradiation target 31 is not limited to the silicon wafer described above, and it is also possible to use such an irradiation target other than the silicon wafer, as a silicon carbide (SiC) wafer or a thin film transistor (TFT) forming substrate.

The optical system moving unit 4, which is connected to the optical system 2, has a function as a moving unit that relatively changes the positional relationship between the optical system 2 and the irradiation target 31. The optical system moving unit 4 moves the optical system 2 in a radial direction of the turntable 3, that is, on a radius line. Specifically, the optical system moving unit 4 horizontally moves the optical system 2 from the in-plane center 3c of the turntable 3 toward the outer periphery of the turntable 3.

Alternatively, the optical system moving unit 4 horizontally moves the optical system 2 from the outer periphery of the turntable 3 toward the in-plane center 3c of the turntable 3.

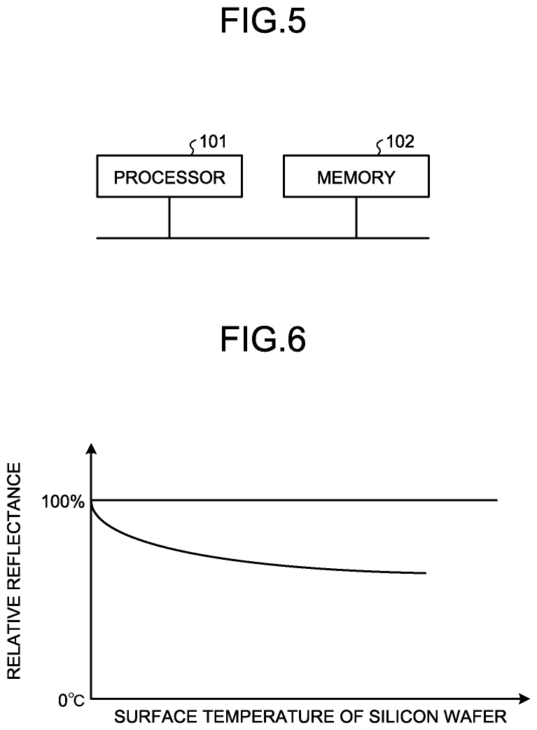

The first control unit 5 is a control unit that controls the drive and position of the laser oscillation unit 1, the turntable 3, the optical system moving unit 4, and the detection unit 9. The first control unit 5 is capable of communicating with the laser oscillation unit 1, the turntable 3, the optical system moving unit 4, and the detection unit 9. Furthermore, the first control unit 5 is implemented as, for example, a processing circuit having a hardware configuration illustrated in FIG. 5. FIG. 5 is a diagram illustrating an example of the hardware configuration of the processing circuit according to the first embodiment of the present invention. In the case where the first control unit 5 is implemented by the processing circuit illustrated in FIG. 5, the first control unit 5 is implemented by, for example, a processor 101 executing a program stored in a memory 102 illustrated in FIG. 5. In addition, a plurality of processors and a plurality of memories may cooperate to implement the above-described function. Furthermore, a part of the function of the first control unit 5 may be implemented as an electronic circuit, and the other part may be implemented by use of the processor 101 and the memory 102.

The laser output measuring unit 6, which is connected to the laser oscillation unit 1, detects an output (W) of laser light oscillated by the laser oscillation unit 1. A laser power meter can be used as the laser output measuring unit 6. The laser power meter is a measuring instrument that allows laser light emitted from the laser oscillation unit 1 to be incident on a sensor light receiving unit for converting the light energy of the laser light into an electric signal for display.

The reflecting mirror 7 has a rectangular shape, and is disposed at a position adjacent to the irradiation target 31 on the upper surface of the base 3a of the turntable 3. The reflecting mirror 7 is provided on an area including an area irradiated with the laser light L on the irradiation target 31, in the radial direction of the turntable 3. Here, the reflecting mirror 7 is provided on an area including an area where the irradiation target 31 is disposed, in the radial direction of the turntable 3.

The detection unit 9 receives first reflected light R1 and second reflected light R2, detects the power, that is, output of the first reflected light R1 and the second reflected light R2, and transmits detection results to the determination unit 10. The first reflected light R1 is first reflected light of the laser light L, which is the laser light L reflected from the irradiation surface of the irradiation target 31 irradiated with the laser light L. The second reflected light R2 is second reflected light of the laser light L, which is the laser light L reflected from the reflecting mirror 7 irradiated with the laser light L. The power (W) of the reflected light detected by the detection unit 9 may be hereinafter referred to as a detection value in some cases. As illustrated in FIG. 3, the objective lens 2b does not direct the laser light L in a direction perpendicular to the upper surface of the base 3a of the turntable 3, but directs the laser light L in a direction at a predetermined angle relative to the upper surface of the base 3a of the turntable 3. Namely, the objective lens 2b does not direct the laser light L in a direction perpendicular to the irradiation surface of the irradiation target 31 disposed on the base 3a of the turntable 3. Rather, the objective lens 2b applies the laser light L to the irradiation surface of the irradiation target 31 at the predetermined angle relative to the irradiation surface of the irradiation target 31.

As described above, the optical system 2 is movable in the radial direction of the turntable 3. The detection unit 9 can be moved by a detection unit moving unit (not illustrated) to a position where the detection unit 9 can detect the laser light L reflected from the irradiation target 31 and the laser light L reflected from the reflecting mirror 7. As an example, the detection unit 9 can be moved to any given height above the in-plane center 3c of the base 3a. As a result, the height of the detection unit 9 is adjusted such that the detection unit 9 detects the laser light L reflected from the irradiation target 31 and the laser light L reflected from the reflecting mirror 7 even when the optical system 2 is moved in the radial direction of the turntable 3. It should be noted that the optical system moving unit 4 and other constituent elements of the heat treatment apparatus 21 are disposed so as not to block the optical paths of the first reflected light R1 and the second reflected light R2.

The determination unit 10 monitors the detection value of the first reflected light R1, transmitted from the detection unit 9 to the determination unit 10, to detect a change in the surface temperature of an area irradiated with the laser light L on the irradiation surface of the irradiation target 31. As a result, the determination unit 10 determines the presence or absence of a change in the surface temperature of the area irradiated with the laser light L on the irradiation target 31. In addition, on the basis of the detection value of the power of the first reflected light R1 and correlation data, the determination unit 10 calculates the surface temperature of the area irradiated with the laser light L on the irradiation target 31. The correlation data shows a correlation between the surface temperature of the irradiation target 31 and the reflectance of the laser light L on the surface of the irradiation target 31.

Furthermore, on the basis of: the detection value of the power of the second reflected light R2 transmitted from the detection unit 9 to the determination unit 10; the reflectance of the laser light L on the surface of the reflecting mirror 7; the detection value of the power of the first reflected light R1 transmitted from the detection unit 9 to the determination unit 10; and the correlation data showing the correlation between the surface temperature of the irradiation target 31 and the reflectance of the laser light L on the surface of the irradiation target 31, the determination unit 10 calculates the surface temperature of the area irradiated with the laser light L on the irradiation target 31.

That is, the determination unit 10 monitors the power (W) of the first reflected light R1, that is, the detection value of the first reflected light R1. As a result of this monitoring, the determination unit 10 determines the presence or absence of a change in the surface temperature of the area irradiated with the laser light L on the irradiation target 31, and also calculates the surface temperature of the area irradiated with the laser light L on the irradiation target 31.

Next, described below is a method for detecting a condition of the surface of the irradiation target 31 in the heat treatment apparatus 21 according to the first embodiment. The heat treatment apparatus 21 according to the first embodiment rotates the turntable 3 with the irradiation targets 31 mounted thereon as illustrated in FIG. 2, at a predetermined rotation speed, and allows the laser light L oscillated by the laser oscillation unit 1 to be applied to the irradiation targets 31 through the optical system 2. The turntable 3 then rotates once, such that the irradiation surfaces of the irradiation targets 31 are subjected to laser annealing with the laser light L along the circumferential direction of the turntable 3, that is, along the direction of rotation of the turntable 3 to thereby provide the irradiation surfaces with annealed strip-like areas having widths equivalent to the beam diameter of the laser light L.

After the turntable 3 rotates once during the irradiation of the irradiation surfaces of the irradiation targets 31 with the laser light L as described above, the optical system moving unit 4 moves the optical system 2 in the radial direction of the turntable 3 by the width equivalent to the beam diameter. Repeating such a process enables the entire surface of each irradiation target 31 to be laser-annealed with the laser light L.

It should be noted that the timing at which to move the optical system 2 in the radial direction of the turntable 3 is not limited to the time when the turntable 3 has rotated once. For example, the optical system 2 may be moved in the radial direction of the turntable 3 each time the turntable 3 rotates twice. Alternatively, the optical system 2 may be moved in the radial direction of the turntable 3 each time the turntable 3 rotates more times. Thus, it is possible to perform a laser annealing process even in the case where the optical system 2 is moved each time the turntable 3 rotates a predetermined number of times.

In the heat treatment apparatus 21, a detection step in which the detection unit 9 detects the power of the first reflected light R1 and the power of the second reflected light R2 is performed during the laser annealing process. Here, in the heat treatment apparatus 21 according to the first embodiment, the laser light L is applied to the irradiation target 31 at a power equivalent to a value of a power density (W/cm²) divided by the scanning speed of the laser light L. The power density (W/cm²) is the amount of heat input per unit time and per unit area when the laser light L is oscillated by the laser oscillation unit 1 and collected by the objective lens 2b. In the heat treatment apparatus 21, the laser light L is applied to the irradiation target 31 such that a value of X/(S×V) is kept constant over the entire irradiation surface of the irradiation target 31, where X is the output of laser light oscillated by the laser oscillation unit 1 and collected by the objective lens 2b, S is the laser-light-irradiated area, and V is the scanning speed at which to scan the irradiation surface of the irradiation target 31 with the laser light L. In other words, the laser light L is applied to the irradiation target 31 such that a value obtained by dividing the output X by the irradiation area S and further by the speed V.

At this time, a major part of the first reflected light R1 advances in such a direction that “the angle of incidence on the irradiation target 31=the angle of reflection from the irradiation target 31” in accordance with the law of reflection. Then, the first reflected light R1 enters the detection unit 9, and the power (W) of the first reflected light R1 is detected by the detection unit 9.

FIG. 6 is a characteristic diagram illustrating a relationship between the relative reflectance of the laser light L and the surface temperature of the silicon wafer that is the irradiation target 31 in the first embodiment of the present invention. Assuming that the reflectance of the laser light L at a specific temperature of the silicon wafer that is the irradiation target 31 is a reference value that is 100%, the relative reflectance means a ratio of the reflectance of the laser light L at a different temperature of the silicon wafer to the reference value. In FIG. 6, the reflectance of the laser light L at the the silicon wafer temperature of 0° C. is the reference value that is 100%.

As illustrated in FIG. 6, the surface temperature of the silicon wafer determines how much of the energy of the laser light L applied to the irradiation surface of the irradiation target 31 is reflected from the irradiation surface of the irradiation target 31. That is, if the energy of the laser light L is constant, the power (W) of light reflected from the irradiation surface of the irradiation target 31 is uniquely determined by the surface temperature of the silicon wafer. In other words, a one-to-one relationship between the surface temperature of the silicon wafer and the power (W) of reflected light from the irradiation surface of the irradiation target 31 holds true.

Furthermore, in the heat treatment apparatus 21 according to the first embodiment, as described above, the laser light L is applied to the irradiation target 31 at a power equivalent to the value obtained by dividing the power density (W/cm²) by the scanning speed of the laser light L. The power density (W/cm²) is the amount of heat input per unit time and per unit area when the laser light L is oscillated by the laser oscillation unit 1, collected by the objective lens 2b, and applied to the irradiation target 31. Then, the above-described power density (W/cm²) that is the amount of heat input is kept constant, and the scanning speed of the laser light L is also kept constant. As a result, the power (W) of the laser light L applied to the irradiation surface of the irradiation target 31 stays constant, and the power (W) of the first reflected light R1 from the irradiation surface of the irradiation target 31 also stays constant.

Then, in a detection value monitoring step, the determination unit 10 monitors the power (W) of the light reflected from the irradiation surface of the irradiation target 31 detected by the detection unit 9, namely, monitors a detection value of the reflected light transmitted from the detection unit 9, thereby detecting a change in the surface temperature of the area irradiated with the laser light L on the irradiation surface of the silicon wafer that is the irradiation target 31. As a result, the determination unit 10 can determine the presence or absence of a change in the surface temperature of the area irradiated with the laser light L.

In the case where the laser light L is applied to the irradiation target 31 while the turntable 3 rotates a plurality of times, the detection unit 9 continuously detects the power (W) of the first reflected light R1 from the irradiation surface of the irradiation target 31, for a period during which the laser light L is applied to the irradiation surface of the irradiation target 31. Then, the determination unit 10 monitors the continuous detection value of the first reflected light R1 transmitted from the detection unit 9. When the continuous detection value of the first reflected light R1 fluctuates, the determination unit 10 determines that the surface temperature is changing in the area irradiated with the laser light L on the irradiation surface of the irradiation target 31. Namely, the determination unit 10 determines that the surface temperature is not constant but varies in the area irradiated with the laser light L on the irradiation surface of the irradiation target 31.

Furthermore, the determination unit 10 monitors the continuous detection value of the first reflected light R1 transmitted from the detection unit 9. When the continuous detection value of the first reflected light R1 does not fluctuate, the determination unit 10 determines that there is no change in the surface temperature in the area irradiated with the laser light L on the irradiation surface of the irradiation target 31. That is, the determination unit 10 determines that the surface temperature is constant in the area irradiated with the laser light L on the irradiation surface of the irradiation target 31.

Through the above-described process, the determination unit 10 can determine whether the surface temperature of the irradiation surface is constant in the area irradiated with the laser light L on the irradiation surface of the irradiation target 31. The determination unit 10 can output a determination result to a display unit (not illustrated) to cause the determination result to be displayed on the display unit. It should be noted that when the laser light L is applied to the irradiation target 31 while the turntable 3 rotates a plurality of times, light reflected from an area other than the irradiation target 31 on the turntable 3 also enters the detection unit 9. In this case, the determination unit 10 can discriminate between the first reflected light R1 from the irradiation surface of the irradiation target 31 and the reflected light from the other area on the turntable 3. This is because the degree of temperature increase and the reflection characteristics vary depending on material.

Furthermore, when the laser light L is applied to the irradiation target 31 while the turntable 3 rotates a plurality of times, the determination unit 10 monitors the detection value of the first reflected light R1 detected at a predetermined detection position on the irradiation surface of the irradiation target 31, transmitted from the detection unit 9. In the case where the detection value of the first reflected light R1 fluctuates during a plurality of performances of detection, the determination unit 10 determines that the surface temperature at the detection position, that is, the surface temperature of the irradiation surface of the irradiation target 31 is changing.

Moreover, in the case where the detection value of the first reflected light R1 detected at the predetermined detection position on the irradiation surface of the irradiation target 31 does not fluctuate during the plurality of performances of the detection, the determination unit 10 determines that the surface temperature at the detection position, that is, the surface temperature of the irradiation surface of the irradiation target 31 is not changing but is kept at a constant value.

Through the above-described process, the determination unit 10 can determine whether the surface temperature is kept at a constant value at the predetermined detection position irradiated with the laser light L on the irradiation surface of the irradiation target 31.

Then, in the case where at least two consecutive detection values do not differ from each other but are equal, the determination unit 10 determines that the surface temperature of the irradiation surface of the irradiation target 31 is kept at a constant value. The determination unit 10 determines that the surface temperature of the silicon wafer is kept at a constant value when equal detection values are consecutively detected a predetermined number of times set in advance in the determination unit 10. An increase in the predetermined number of times increases the accuracy of determination that the surface temperature of the silicon wafer is kept at a constant value.

When the determination unit 10 determines that the surface temperature at the detection position stays constant in the area irradiated with the laser light L on the irradiation surface of the irradiation target 31, the determination unit 10 can determine that the surface temperature of the entire area irradiated with the laser light L on the irradiation surface of the irradiation target 31 is uniformly kept at a constant value.

In the heat treatment apparatus 21, as discussed above, the first reflected light R1 from the irradiation surface of the irradiation target 31 is directly measured and hence detected and a relative variation in the detection values is monitored, such that it is possible to verify the presence or absence of a relative variation in the surface temperature in the area irradiated with the laser light L on the silicon wafer that is the irradiation target 31 disposed on the turntable 3. In addition, when a plurality of silicon wafers that are the irradiation targets 31 is disposed on the turntable 3, it is possible to verify the presence or absence of a relative variation in the surface temperature of the area irradiated with the laser light L between the plurality of silicon wafers disposed on the turntable 3 and verify a relative variation in the surface temperature between positions in the area irradiated with the laser light L on a single silicon wafer.

Furthermore, the reflecting mirror 7 reflects all the energy of the laser light L. Accordingly, no temperature increase occurs on the surface of the reflecting mirror 7. Therefore, the detection value of the second reflected light R2 from the surface of the reflecting mirror 7 is kept at a constant value regardless of the surface temperature of the reflecting mirror 7.

The determination unit 10 monitors the relative intensity between the detection value of the second reflected light R2 from the surface of the reflecting mirror 7 and the detection value of the first reflected light R1 from the irradiation surface of the irradiation target 31, such that the determination unit 10 can determine, with higher accuracy, the presence or absence of a change in the surface temperature of the area irradiated with the laser light L on the silicon wafer.

Furthermore, by monitoring the relative intensity between the detection value of the second reflected light R2 from the surface of the reflecting mirror 7 and the detection value of the first reflected light R1 from the irradiation surface of the irradiation target 31, the determination unit 10 can measure the surface temperature of the silicon wafer with higher accuracy.

The output of the laser light L is not completely constant, and fluctuates within a certain range with respect to the output value of the laser light L set as a target value in advance in the first control unit 5. The fluctuation range of the output of the laser light L varies depending on various conditions such as the quality of the laser oscillation unit 1, the degree of deterioration of the laser oscillation unit 1, and the environment of usage of the laser oscillation unit 1. In some case, the fluctuation range is approximately 10% of the target output value of the laser light L in the long term although it is not always the case. Although it may be possible to directly measure the power of the laser light L on the optical path of the laser light L by means of the laser output measuring unit 6, it is in general difficult to directly measure the power of the laser light L on the optical path following the condenser lens that serves as a final optical lens for guiding the laser light L to the irradiation target 31.

In addition, in some case, the laser light L coming out of the objective lens 2b that is the condenser lens may be attenuated before the laser light L is applied to the irradiation target 31. Moreover, the amount of attenuation varies with a change in conditions such as the amount of moisture in the atmosphere, the amount of impurity gas in the atmosphere, and the state of protective glass that may be disposed on the upper surface of the irradiation target 31 in some cases. This means that, where only the detection value of the reflected light from the irradiation surface of the irradiation target 31 is detected, it cannot be determined whether the change in the detection value indicates that the output of the laser light has changed or the surface temperature of the irradiation surface of the irradiation target 31 has actually changed.

To address this issue, the heat treatment apparatus 21 monitors the relative amount of change in the detection value of the first reflected light R1 from the irradiation surface of the irradiation target 31 with respect to the reference value that is the detection value of the second reflected light R2 from the surface of the reflecting mirror 7. As a result, it is possible for the heat treatment apparatus 21 to measure, with higher accuracy, the surface temperature of the irradiation surface of the irradiation target 31 without being affected by a change in the original output of the laser light L oscillated by the laser oscillation unit 1, or without being affected by attenuation of the laser light L that may occur before the laser light L coming out of the objective lens 2b is applied to the irradiation target 31.

That is, a reflectance M of the laser light L on the surface of the reflecting mirror 7 is known and constant. Therefore, the determination unit 10 divides the detection value of the second reflected light R2 from the surface of the reflecting mirror 7 by the reflectance M, namely, divides the power (W) of the second reflected light R2 by the reflectance M to thereby calculate the irradiation output of the laser light L oscillated by the laser oscillation unit 1, collected by the objective lens 2b, and applied to the reflecting mirror 7. The irradiation output of the laser light L oscillated by the laser oscillation unit 1, collected by the objective lens 2b, and applied to the irradiation surface of the irradiation target 31 is equal to the irradiation output of the laser light L applied to the reflecting mirror 7. On the basis of: the detection value of the second reflected light R2 from the surface of the reflecting mirror 7; and the reflectance M of the reflecting mirror 7, the determination unit 10 can obtain the irradiation output of the laser light L applied to the irradiation surface of the irradiation target 31.

Next, the determination unit 10 calculates the reflectance of the laser light L on the irradiation surface of the irradiation target 31 by dividing the detection value of the first reflected light R1 from the irradiation surface of the irradiation target 31 by the irradiation output of the laser light L applied to the irradiation surface of the irradiation target 31. Namely, the determination unit 10 can obtain the reflectance of the laser light L on the irradiation surface of the irradiation target 31 on the basis of: the detection value of the first reflected light R1 from the irradiation surface of the irradiation target 31; and the irradiation output of the laser light L applied to the irradiation surface of the irradiation target 31. The reflectance corresponds to the relative reflectance illustrated in FIG. 6.

Next, the determination unit 10 calculates the surface temperature of the irradiation surface of the irradiation target 31 on the basis of: the relative reflectance of the laser light L obtained by the calculation; and the correlation data showing the correlation between the surface temperature of the silicon wafer and the relative reflectance of the laser light L, illustrated in FIG. 6. The determination unit 10 stores, in advance, the correlation data showing the correlation between the surface temperature of the silicon wafer and the relative reflectance of the laser light L, illustrated in FIG. 6.

Accordingly, in the heat treatment apparatus 21, the determination unit 10 performs the above-described detection value monitoring step of monitoring the detection value of the second reflected light R2 from the surface of the reflecting mirror 7 and the detection value of the first reflected light R1 from the irradiation surface of the irradiation target 31. In addition, the determination unit 10 uses the correlation data illustrated in FIG. 6. As a result, the determination unit 10 can measure, with higher accuracy, the surface temperature of the irradiation surface of the irradiation target 31.

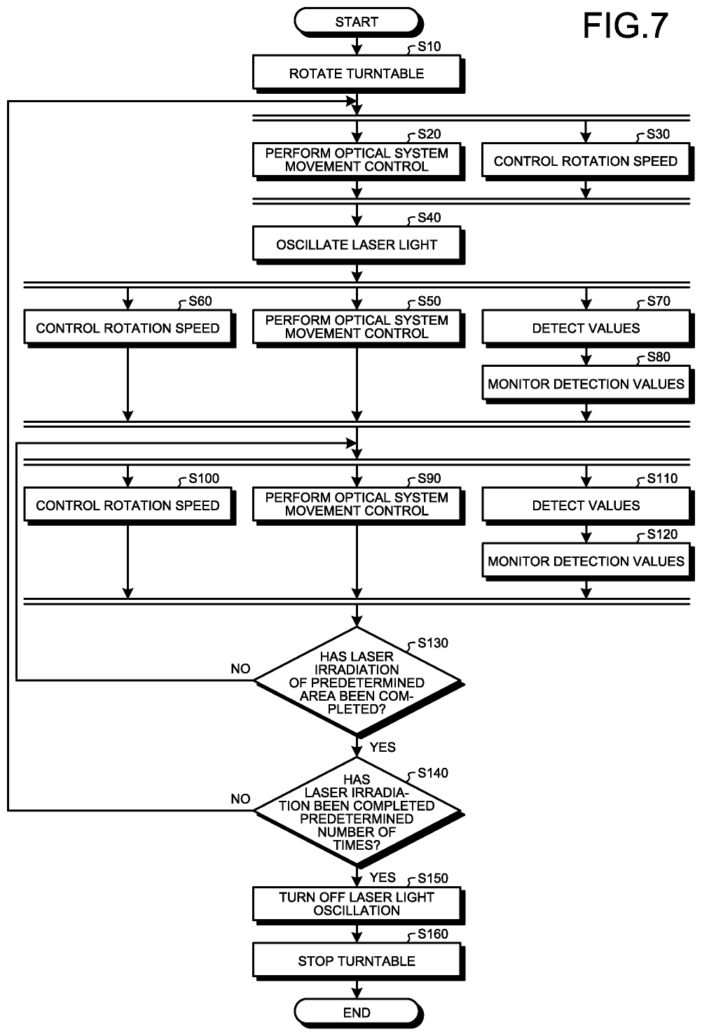

Next, described below is a heat treatment operation of the heat treatment apparatus 21 according to the first embodiment. FIG. 7 is a flowchart illustrating a procedure of the heat treatment operation of the heat treatment apparatus 21 according to the first embodiment of the present invention. A heat treatment method according to the first embodiment includes an irradiation step of applying the laser light L to an irradiation target that is to be irradiated with laser light, a detection step of detecting the power of the reflection of the laser light L from the surface of the irradiation target, and a determination step of determining on the basis of a detection value of the detected power of the reflection the presence or absence of a change in the surface temperature of an area irradiated with the laser light L on the irradiation target. The above-described irradiation step can be performed in steps S10 to S60, step S90, and step S100. The detection step can be performed in steps S70 and S110. The determination step can be performed in steps S80 and S120.

First, in step S10, the first control unit 5 controls the motor (not illustrated) to rotate the turntable 3 holding thereon five silicon wafers that are the irradiation targets 31 as illustrated in FIG. 2.

When the rotation speed of the turntable 3 reaches a predetermined rotation speed set in advance, that is, when the number of revolutions of the turntable 3 reaches a predetermined number of revolutions set in advance, the first control unit 5 causes the optical system moving unit 4 to perform control so as to move the optical system 2 to a predetermined initial position in the radial direction of the turntable 3 in step S20.

Furthermore, in parallel with step S20, the first control unit 5 starts, in step S30, a control process of controlling the rotation speed of the turntable 3 to increase the circumferential speed of the laser light L at an irradiation position at which the laser light L is applied from the optical system 2 to the irradiation surfaces of the irradiation targets 31, to a predetermined circumferential speed. It should be noted that step S30 may be performed after the completion of step S20. Alternatively, step S20 may be performed after the completion of step S30. Thus, the order in which steps S20 and S30 are performed does not really matter.

The scan trajectory of the laser light L and the scanning circumferential speed of the laser light L at the time of irradiation of the irradiation surface with the laser light L are predetermined. Thus, the position of the optical system 2 in the radial direction of the turntable 3 and the rotation speed of the turntable 3 are uniquely determined. As a result, the rotation speed of the turntable 3 and the position of the optical system 2 can be controlled by feedforward control in steps S20 and S30. Also, the rotation speed of the turntable 3 and the drive point of the optical system 2 are controlled with the position of the optical system 2 and the rotation speed of the turntable 3 being fed back so that the circumferential speed on the individual irradiation surfaces of the irradiation targets 31 are kept constant during the laser annealing process.

In step S40 parallel with step S30, the first control unit 5 turns on the laser oscillation unit 1, performs control such that the laser oscillation unit 1 starts oscillating the laser light L to start irradiating the irradiation surfaces of the irradiation targets 31 with the laser light L. It should be noted that step S40 may be performed after the start of step S30.

Then, as described above, the first control unit 5 performs control such that the irradiation surfaces of the irradiation targets 31 are irradiated with the laser light L at a constant power of X/(S×V). That is, in step S50, the first control unit 5 controls the optical system moving unit 4 such that the optical system 2 is held at a predetermined position in the radial direction of the turntable 3. Furthermore, in step S60 parallel with step S50, the first control unit 5 performs control for maintaining the rotation speed of the turntable 3 such that the circumferential speed of the laser light L at the irradiation position at which the laser light L is applied from the optical system 2 to the irradiation surfaces of the irradiation targets 31 is kept at the predetermined circumferential speed. As a result, the irradiation target 31 is subjected to annealing at its annular area having a width equivalent to the width of the laser light L.

Moreover, in parallel with steps S50 and S60, the detection unit 9 performs, in step S70, the detection step of detecting values, and the determination unit 10 performs, in step S80, the detection value monitoring step on the basis of results of detection in the detection step.

In the detection step of step S70, as discussed above, the detection unit 9 detects the power of the first reflected light R1, which is the laser light L reflected from the surface of the irradiation target 31. The detection unit 9 also detects the power of the second reflected light R2, which is the laser light L reflected from the surface of the reflecting mirror 7.

In addition, in the detection value monitoring step of step S80, the determination unit 10 monitors the relative intensity between the detection value of the second reflected light R2 from the surface of the reflecting mirror 7 and the detection value of the first reflected light R1 from the irradiation surface of the irradiation target 31, as described above, such that the determination unit 10 detects a change in the surface temperature of the area irradiated with the laser light L on the irradiation surface of the irradiation target 31. Thus, the determination unit 10 determines the presence or absence of a change in the surface temperature of the area irradiated with the laser light L. Furthermore, as described above, the determination unit 10 measures the surface temperature of the silicon wafer with higher accuracy, by monitoring the relative intensity between the detection value of the second reflected light R2 from the surface of the reflecting mirror 7 and the detection value of the first reflected light R1 from the irradiation surface of the irradiation target 31. Moreover, in the detection value monitoring step, the determination unit 10 can calculate the surface temperature of the area irradiated with the laser light L on the irradiation target 31, on the basis of: the detection value of the power of the first reflected light R1; and the correlation data showing the correlation between the surface temperature of the irradiation target 31 and the reflectance of the laser light L on the surface of the irradiation target 31.

Then, as described above, the turntable 3 rotates a predetermined number of times during the irradiation of the irradiation surfaces of the irradiation targets 31 with the laser light L. Subsequently, in step S90, the first control unit 5 performs optical system movement control on the optical system moving unit 4 such that the optical system 2 moves in the radial direction of the turntable 3 by the width of the laser light L that is to be applied to the irradiation targets 31.

Furthermore, in step S100 parallel with step S90, the first control unit 5 starts rotation speed control for controlling the rotation speed of the turntable 3 such that the circumferential speed of the laser light L at the irradiation position at which the laser light L is applied from the optical system 2 to the irradiation surfaces of the irradiation targets 31 is increased to the predetermined circumferential speed. Here, the predetermined circumferential speed refers to the circumferential speed of the laser light L that is to be applied to the irradiation surfaces of the irradiation targets 31 at the constant power of X/(S×V).

Moreover, in parallel with steps S90 and S100, the detection unit 9 performs, in step S110, the detection step of detecting values, and the determination unit 10 performs, in step S120, the detection value monitoring step on the basis of results of detection in the detection step.

Then, the turntable 3 rotates a predetermined number of revolutions during the irradiation of the irradiation surfaces of the irradiation targets 31 with the laser light L. Subsequently, in step S130, the first control unit 5 determines whether the irradiation of a predetermined irradiation surface with the laser light L has been completed, that is, determines whether the optical system 2 has completed scanning an irradiation area set in advance.

In the case of No in step S130, or where the irradiation of the predetermined irradiation surface with the laser light L has not been completed, steps S90 to S120 are repeated.

In the case of Yes in step S130, or where the optical system 2 has completed scanning the preset irradiation area without leaving any irradiation surface unirradiated with the laser light L, the first control unit 5 determines, in step S140, whether the laser irradiation of the predetermined irradiation surface has been completed a predetermined number of times. Namely, the first control unit 5 determines, in step S140, whether the optical system 2 has completed scanning the preset irradiation area the predetermined number of times. Here, the predetermined number of times is equal to or more than twice.

In the case of No in step S140, or where the laser irradiation of the predetermined irradiation surface has not been completed the predetermined number of times, steps S20 to S130 are repeated. In this case, the laser light L has already been oscillated, and thus step S40 is omitted.

Meanwhile, in the case of Yes in step S140, or where the laser irradiation of the predetermined irradiation surface has been completed the predetermined number of times, the first control unit 5 performs control such that the laser oscillation unit 1 is turned off to terminate oscillation of the laser light L, in step S150. Then, in step S160, the first control unit 5 performs control for stopping the turntable 3. As a result, a series of laser annealing processes is completed.

As described above, when performing the irradiation with the laser light L once, the heat treatment apparatus 21 can detect the surface temperature of the preset irradiation surface and a change in the surface temperature by performing the detection step and the detection value monitoring step in performing irradiation with the laser light L at each position in the radial direction of the turntable 3. Furthermore, when performing the irradiation with the laser light L a plurality of times, the heat treatment apparatus 21 can detect the surface temperature of the preset irradiation surface and a change in the surface temperature each time irradiation with the laser light L is performed, by performing the detection step and the detection value monitoring step in performing irradiation with the laser light L at each position in the radial direction of the turntable 3. Therefore, the heat treatment apparatus 21 can detect a change in the surface temperature and an end-point temperature of the irradiation surface of the irradiation target 31.

It should be noted that the case where the irradiation target 31 is a silicon wafer has been described above. Even when the irradiation target 31 is a substance other than a silicon wafer, as in the above, it is possible to verify the presence or absence of a relative variation in surface temperature among a plurality of the irradiation targets 31 made of the same material or verify the presence or absence of a relative variation in surface temperature among positions on the surface of the single irradiation target 31.

As described above, the heat treatment apparatus 21 according to the first embodiment monitors the relative intensity between the detection value of the second reflected light R2 from the surface of the reflecting mirror 7 and the detection value of the first reflected light R1 from the irradiation surface of the irradiation target 31, such that the heat treatment apparatus 21 can detect a change in the surface temperature of the area irradiated with the laser light L on the irradiation surface of the irradiation target 31, and measure the surface temperature of the silicon wafer with high accuracy.

Therefore, the heat treatment apparatus 21 according to the first embodiment is a heat treatment apparatus simply configured to detect the temperature state of the laser-irradiated portion with high accuracy.

### Second Embodiment

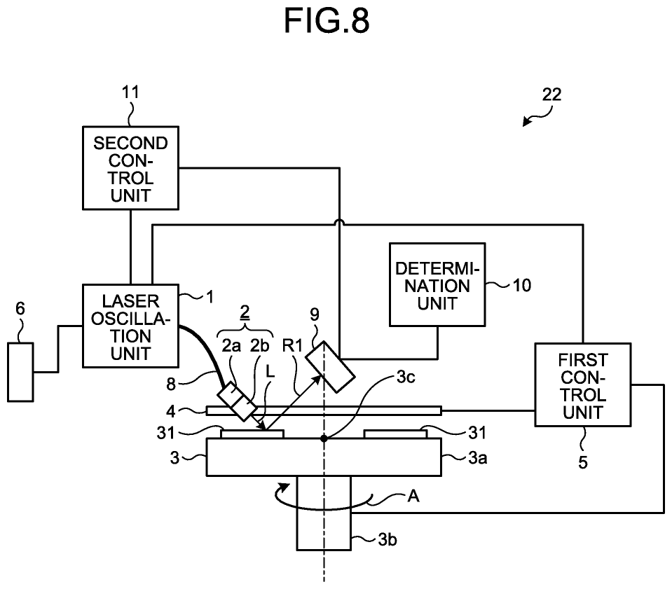

FIG. 8 is a schematic diagram illustrating the configuration of a heat treatment apparatus 22 according to a second embodiment of the present invention. The heat treatment apparatus 22 according to the second embodiment of the present invention differs from the heat treatment apparatus 21 according to the first embodiment in that the heat treatment apparatus 22 includes a second control unit 11. The heat treatment apparatus 22 according to the second embodiment of the present invention has the same configuration as the heat treatment apparatus 21 according to the first embodiment except that the heat treatment apparatus 22 includes the second control unit 11.

As described above, the output of the laser light L is not completely constant, and fluctuates within a certain range with respect to the target output value of the laser light L preset in the first control unit 5. When the output of the laser light L fluctuates, there is a possibility that the temperature of the irradiation target 31 cannot be increased to a desired temperature, or may be excessively increased to a temperature higher than the desired temperature.

The second control unit 11 is a control unit that, in a laser output control step, controls the output of the laser light L oscillated by the laser oscillation unit 1, on the basis of a detection value detected by the detection unit 9 and a target detection value. That is, the second control unit 11 is capable of communicating with the detection unit 9, and a detection value of the first reflected light R1 is transmitted from the detection unit 9.

The second control unit 11 stores, in advance, a predetermined target detection value of the first reflected light R1. Here, a predetermined target temperature refers to a detection value of the first reflected light R1 detected in the case where the laser light L of an appropriately preset output increases the temperature of the irradiation target 31 to a desired temperature. The second control unit 11 controls the laser oscillation unit 1 such that the detection value of the first reflected light R1 becomes close to the target detection value. That is, the second control unit 11 performs feedback control that, on the basis of the detection value detected by the detection unit 9 and the target detection value, determines the output of the laser light L to bring the detection value of the first reflected light R1 close to the target detection value. Thus, the laser oscillation unit 1 is driven with the determined output.

Namely, the second control unit 11 controls the laser oscillation unit 1 to bring the detection value of the first reflected light R1 close to the target detection value. Thus, the heat treatment apparatus 22 can stably increase the surface temperature of the irradiation target 31 to a predetermined temperature as designed.

It should be noted that the case where the predetermined target detection value is stored in the second control unit 11 has been described here. However, a value detected at the start of an annealing process in the heat treatment apparatus 22 or the average of values detected for any given period from the start of the annealing process may be set as the target detection value. As a result, the heat treatment apparatus 22 can provide stable heat treatment as the heat treatment apparatus 22 beings the detection value of the first reflected light R1 close to the target detection value determined in advance or during the annealing process.

Furthermore, the second control unit 11 is implemented as, for example, a processing circuit with the hardware configuration illustrated in FIG. 5. In the case where the second control unit 11 is implemented by the processing circuit illustrated in FIG. 5, the second control unit 11 is implemented by, for example, the processor 101 executing a program stored in the memory 102 illustrated in FIG. 5. In addition, a plurality of processors and a plurality of memories may cooperate to implement the above-described function. Furthermore, a part of the function of the second control unit 11 may be implemented as an electronic circuit, and the other part may be implemented by use of the processor 101 and the memory 102.

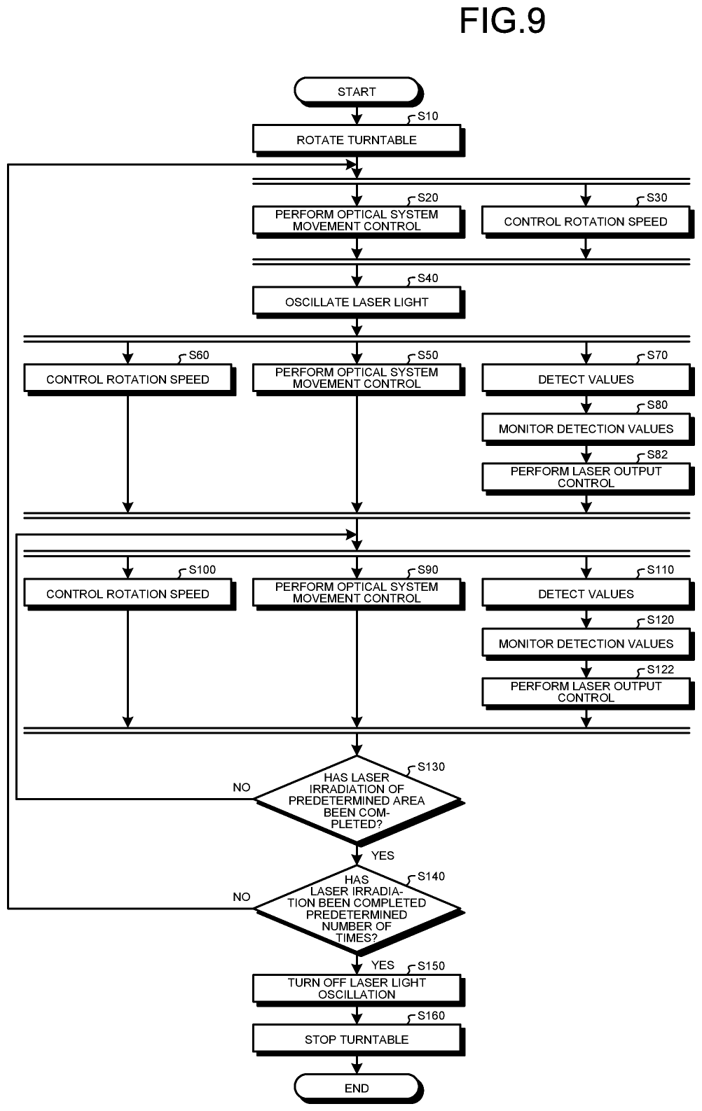

Next, described below is a heat treatment operation of the heat treatment apparatus 22 according to the second embodiment. FIG. 9 is a flowchart illustrating a procedure of the heat treatment operation of the heat treatment apparatus 22 according to the second embodiment of the present invention.

The basic heat treatment operation of the heat treatment apparatus 22, illustrated in the flowchart of FIG. 9, is the same as the heat treatment operation of the heat treatment apparatus 21 according to the first embodiment, illustrated in the flowchart of FIG. 7. Therefore, description of the same process as that illustrated in the flowchart of FIG. 7 will be omitted, and a process different from the heat treatment operation illustrated in the flowchart of FIG. 7 will be described here.

Subsequent to step S80, the heat treatment apparatus 22 performs the above-described laser output control step in step S82. Namely, the second control unit 11 performs feedback control that, on the basis of the detection value detected by the detection unit 9 and the target detection value, determines the output of the laser light L to bring the detection value of the first reflected light R1 close to the target detection value. Thus, the laser oscillation unit 1 is driven with the determined output. In addition, subsequent to step S120, the heat treatment apparatus 22 performs the above-described laser output control step in step S122.

As described above, in addition to the effect that can be achieved by the heat treatment apparatus 21 according to the first embodiment, the heat treatment apparatus 22 according to the second embodiment can also achieve an effect of enabling stable heat treatment by bringing the detection value of the first reflected light R1 close to the target detection value set in advance or during the annealing process.

### Third Embodiment

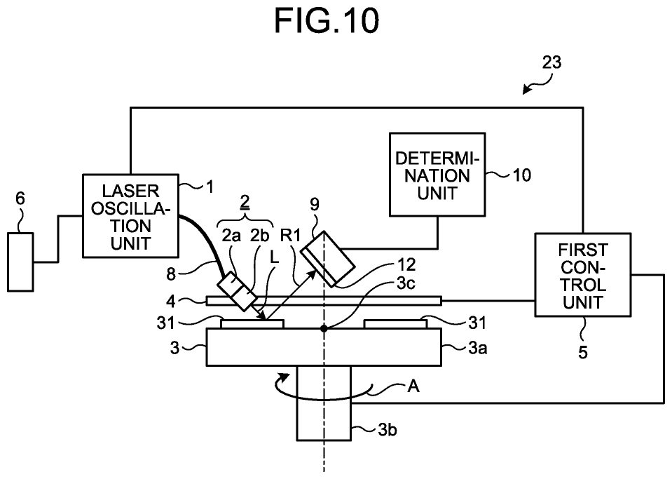

FIG. 10 is a schematic diagram illustrating the configuration of a heat treatment apparatus 23 according to a third embodiment of the present invention. The heat treatment apparatus 23 according to the third embodiment of the present invention differs from the heat treatment apparatus 22 according to the second embodiment in that the heat treatment apparatus 23 includes an attenuation filter 12. The heat treatment apparatus 23 according to the third embodiment of the present invention has the same configuration as the heat treatment apparatus 22 according to the second embodiment except that the heat treatment apparatus 23 includes the attenuation filter 12.

Increasing the rotation speed of the turntable 3 is effective in increasing the processing ability of the heat treatment apparatus 22 according to the second embodiment. Meanwhile, when increasing the rotation speed of the turntable 3, it is necessary to increase the output of the laser light L so as to prevent the power of the laser light L to be applied to the irradiation surface of the irradiation target 31 from decreasing, that is, the value of X/(S×V) described above from decreasing due to an increase in the rotation speed of the turntable 3.

As a matter of course, the optical intensity of the reflected laser light L increases as the output of the laser light L increases. Namely, the optical intensity of the reflected laser light L increases as the output of the laser light L increases. Here, the optical intensity is represented by the illuminance of the laser light L incident on the irradiation surface of the irradiation target 31. Namely, the optical intensity is represented by incident light flux per unit area. Then, the optical intensity of the reflected laser light L exceeds an allowable threshold of the optical intensity of the reflected laser light L detectable by the detection unit 9. Namely, as the output of the laser light L increases, the optical intensity of the first reflected light R1 and the second reflected light R2 increases. Then, the optical intensity of the second reflected light R2 exceeds the allowable threshold of the optical intensity of the reflected laser light L detectable by the detection unit 9. When the output of the laser light L is further increased, the optical intensity of the first reflected light R1 and the optical intensity of the second reflected light R2 exceed the allowable threshold detectable by the detection unit 9.

Generally, a small-sized detector intended for installation inside a processing apparatus can detect a laser light optical intensity of 2 W to 3 W. The detector may be damaged in the case where the optical intensity of laser light incident on the detector exceeds an allowable threshold of the optical intensity of laser light detectable by the detector, that is, in the case where laser light has an optical intensity of, for example, 100 W. It is therefore necessary to provide an attenuation filter that attenuates, at a constant rate, the optical intensity of laser light incident on the detection unit in the case where the detection unit detects laser light with an optical intensity exceeding an allowable threshold of the optical intensity of laser light detectable by the detection unit.

To address that issue, the heat treatment apparatus 23 according to the third embodiment includes the attenuation filter 12 that attenuates, at a constant rate, the optical intensity of the reflected laser light L incident on the detection unit 9. The attenuation filter 12 is disposed on a surface of the detection unit 9 on which the first reflected light R1 is incident. Namely, that is, the attenuation filter 12 is disposed upstream of the detection unit 9 on an optical path of the reflected laser light L. In other words, the attenuation filter 12 is disposed upstream of the detection unit 9 on the optical path of the first reflected light R1 and the optical path of the second reflected light R2. Then, the attenuation filter 12 attenuates, at a constant rate, the optical intensity of the reflected laser light L incident on the attenuation filter 12, and allows the light having the optical intensity attenuated to enter the detection unit 9. That is, the attenuation filter 12 attenuates the optical intensity of the first reflected light R1, at the constant rate, and allows the attenuated first reflected light R1 to enter the detection unit 9. Furthermore, the attenuation filter 12 attenuates the optical intensity of the second reflected light R2 at the constant rate, and allows the attenuated second reflected light R2 to enter the detection unit 9.

As a result, reflected light having an optical intensity exceeding the allowable threshold detectable by the detection unit 9 can be attenuated to a value equal to or less than the allowable threshold by the heat treatment apparatus 23 according to the third embodiment. The heat treatment apparatus 23 allows the reflected light attenuated as above to enter the detection unit 9. The detection unit 9 detects the power of the reflected light received through the attenuation filter 12. Furthermore, the detection unit 9 stores information on an attenuation rate at which the optical intensity of the reflected light is attenuated at the attenuation filter 12. The detection unit 9 can calculate the power of the pre-attenuation reflected light incident on the attenuation filter 12 on the basis of: the power of the reflected light received through the attenuation filter 12; and the information on the attenuation rate at which the optical intensity of the reflected light is attenuated at the attenuation filter 12. The detection unit 9 transmits the calculated detection value to the determination unit 10. The determination unit 10 can perform a process similar to that in the first embodiment, by using the detection value received from the detection unit 9.

As a result, the heat treatment apparatus 23 can detect the temperature state of the laser-irradiated portion without damaging the detection unit 9 even when the optical intensity of the reflected laser light L exceeds the allowable threshold of the optical intensity of the reflected laser light L detectable by the detection unit 9. In addition, the heat treatment apparatus 23 can detect, with high accuracy, the temperature state of the laser-irradiated portion with a simple configuration without damaging the detection unit 9 even when increasing the rotation speed of the turntable 3 and also increasing the output of the laser light L so as to increase production capacity. It should be noted that in accordance with the allowable threshold of the optical intensity of laser light detectable by the detection unit 9 and the ability of the attenuation filter 12 to attenuate the laser light L, the upper limit of the output of the laser light L is set taking into consideration the durability of the irradiation target 31 and the reflecting mirror 7 with respect to the laser light L.

The heat treatment operation of the heat treatment apparatus 23 according to the third embodiment is basically the same as the heat treatment operation of the heat treatment apparatus 22 according to the second embodiment. However, in the detection steps of steps S70 and S110, the first reflected light R1 enters the attenuation filter 12, and is attenuated at the constant rate such that the optical intensity decreases to a value equal to or less than the allowable threshold detectable by the detection unit 9. Then, the attenuated first reflected light R1 enters the detection unit 9 and is detected by the detection unit 9. Similarly, in the detection steps of steps S70 and S110, the second reflected light R2 enters the attenuation filter 12, and is attenuated at the constant rate such that the optical intensity decreases to a value equal to or less than the allowable threshold detectable by the detection unit 9. Then, the attenuated second reflected light R2 enters the detection unit 9 and is detected by the detection unit 9.

As described above, in addition to the effect that can be achieved by the heat treatment apparatus 22 according to the second embodiment, the heat treatment apparatus 23 according to the third embodiment can also achieve an effect of improving production capacity by increasing the rotation speed of the turntable 3 and increasing the output of the laser light L, without damaging the detection unit 9.

It should be noted that although the heat treatment apparatus 22 according to the second embodiment with the attenuation filter 12 added has been described above, the attenuation filter 12 may be added to the heat treatment apparatus 21 according to the first embodiment. In the case where the attenuation filter 12 is added to the heat treatment apparatus 21 according to the first embodiment, it is possible to achieve an effect of improving production capacity without damaging the detection unit 9 as described above, in addition to the effect that can be achieved by the heat treatment apparatus 21.

### Fourth Embodiment

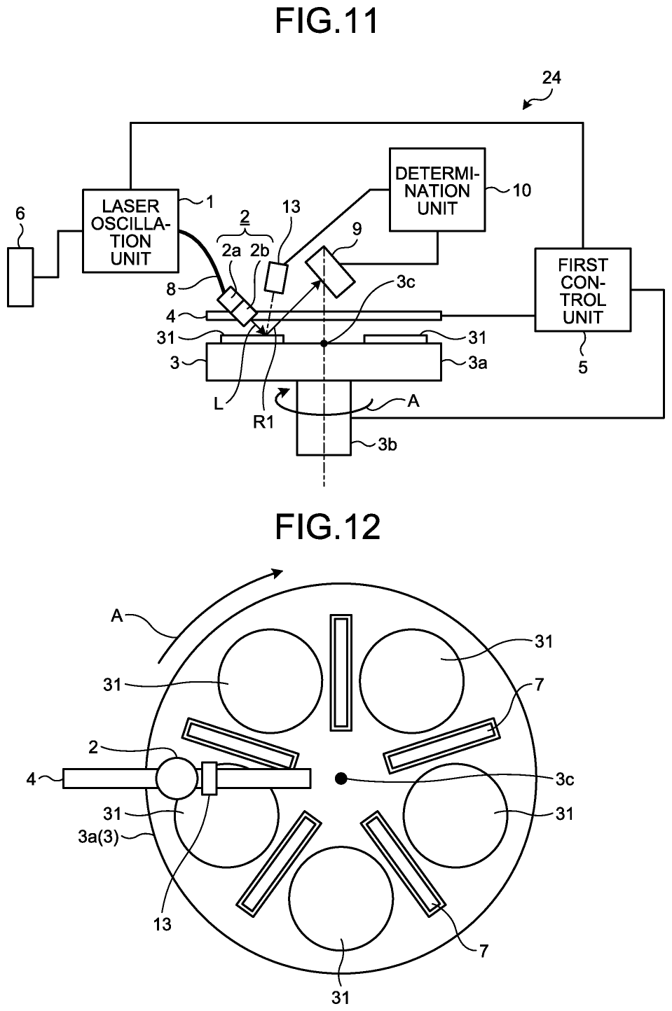

FIG. 11 is a schematic diagram illustrating the configuration of a heat treatment apparatus 24 according to a fourth embodiment of the present invention. FIG. 12 is a plan view illustrating a main part of the configuration of the heat treatment apparatus 24 according to the fourth embodiment of the present invention. FIG. 12 illustrates the peripheral part of the turntable 3 in the heat treatment apparatus 24. The heat treatment apparatus 24 according to the fourth embodiment of the present invention differs from the heat treatment apparatus 21 according to the first embodiment in that the heat treatment apparatus 24 includes an imaging element unit 13 as another detection unit. The heat treatment apparatus 24 according to the fourth embodiment of the present invention has the same configuration as the heat treatment apparatus 21 according to the first embodiment except that the heat treatment apparatus 24 includes the imaging element unit 13.

Increasing the rotation speed of the turntable 3 is effective in increasing the processing ability of the heat treatment apparatus 21 according to the first embodiment, as described above. Meanwhile, when increasing the rotation speed of the turntable 3, it is necessary to increase the output of the laser light L so as to prevent the power of the laser light L to be applied to the irradiation surface of the irradiation target 31 from decreasing, that is, the above-discussed value of X/(S×V) from decreasing due to an increase in the rotation speed of the turntable 3.

Then, as described above, the optical intensity of the reflected laser light L increases as the output of the laser light L increases. Namely, the optical intensity of the reflected laser light L increases as the output of the laser light L increases.

In general, some semiconductor substrates for use in manufacturing semiconductor devices have smooth surfaces. In the case where a semiconductor substrate having a smooth surface is the irradiation target 31 in the heat treatment apparatus 21 according to the first embodiment, most of the laser light L applied to the irradiation surface of the semiconductor substrate directly becomes the first reflected light R1 due to regular reflection. Then, a very small part of the laser light L applied to the irradiation surface of the semiconductor substrate becomes light due to diffuse reflection. Thus, the diffusely reflected light is less generated on the irradiation surface of the semiconductor substrate. Therefore, even if the diffusely reflected laser light L from the surface of the semiconductor substrate is observed, it is not possible to accurately identify and detect the diffusely reflected light. This is because the optical intensity of the diffusely reflected light is very small. For example, even if the diffusely reflected light is observed from the incident side of the laser light L on the irradiation surface of the semiconductor substrate or from a direction orthogonal to an incident direction, it is not possible to accurately identify and detect the diffusely reflected light generated on the irradiation surface of the semiconductor substrate because the optical intensity of the diffusely reflected light is very small.

However, an increase in the output of the laser light L also increases the diffusely reflected light generated on the irradiation surface of the semiconductor substrate when the laser light L is applied to the irradiation surface of the semiconductor substrate. The imaging element unit 13 detects the intensity of the diffusely reflected light, such that the power of the reflected light from the irradiation surface of the semiconductor substrate and the irradiation surface of the reflecting mirror 7 can be obtained from the brightness of the diffusely reflected light detected by the imaging element unit 13.

Namely, the heat treatment apparatus 24 does not use the detection unit 9 in the case where the optical intensity of the reflected laser light L exceeds the allowable threshold of the optical intensity of the reflected laser light L detectable by the detection unit 9. In such a case, instead of the detection unit 9, the imaging element unit 13 is used as a detection unit for detecting the power of the first reflected light R1 and the second reflected light R2. Regarding the first reflected light R1, the imaging element unit 13 detects the power, that is, output of the first reflected light R1 by detecting diffusely reflected light that is lower in optical intensity than regularly reflected light and generated on the irradiation surface of the semiconductor substrate when the laser light L is applied to the irradiation surface of the semiconductor substrate. Furthermore, regarding the second reflected light R2, the imaging element unit 13 detects the power, that is, output of the second reflected light R2 by detecting diffusely reflected light that is lower in optical intensity than regular reflection and generated on the irradiation surface of the reflecting mirror 7 when the laser light L is applied to the irradiation surface of the reflecting mirror 7.

The imaging element unit 13 stores brightness-power correlation data showing a correlation between the brightness of diffusely reflected light from the irradiation surface on the turntable 3 detected by the imaging element unit 13 and the power of reflected light from the irradiation surface on the turntable 3. The imaging element unit 13 can calculate the power of reflected light from the irradiation surface on the turntable 3 by using: the detected brightness of the diffusely reflected light from the irradiation surface on the turntable 3; and the brightness-power correlation data. The imaging element unit 13 detects the diffusely reflected light that resulting from the diffuse reflection of the laser light L from the irradiation surface on the turntable 3. The imaging element unit 13 uses information on the detected diffusely reflected light to detect the power of the reflected light from the irradiation surface on the turntable 3, i.e., the power of the first reflected light R1 and the power of the second reflected light R2.

That is, the imaging element unit 13 stores correlation data on a correlation between the brightness and the power of the first reflected light R1. The correlation data shows a correlation between the power of the first reflected light R1 generated on the irradiation surface of the semiconductor substrate and the brightness of the diffusely reflected light generated on the irradiation surface of the semiconductor substrate and detected by the imaging element unit 13 when the laser light L is applied to the irradiation surface of the semiconductor substrate. Using the detected brightness of the diffusely reflected light from the irradiation surface on the turntable 3 and the correlation data on the correlation between the brightness and the power of the first reflected light R1, the imaging element unit 13 calculates the power of the first reflected light R1 and hence detects the power of the first reflected light R1. The imaging element unit 13 transmits, to the determination unit 10, the calculated power of the first reflected light R1.

In addition, the imaging element unit 13 stores correlation data on a correlation between the brightness and the power of the second reflected light R2. The correlation data shows a correlation between the power of the second reflected light R2 generated on the irradiation surface of the reflecting mirror 7 and the brightness of the diffusely reflected light generated on the irradiation surface of the reflecting mirror 7 and detected by the imaging element unit 13 when the laser light L is applied to the irradiation surface of the reflecting mirror 7. Using the detected brightness of the diffusely reflected light from the irradiation surface on the turntable 3 and the correlation data on the correlation between the brightness and the power of the second reflected light R2, the imaging element unit 13 calculates the power of the second reflected light R2 and hence detects the power of the second reflected light R2. The imaging element unit 13 transmits, to the determination unit 10, the calculated power of the second reflected light R2.

The determination unit 10 can perform a process similar to that in the first embodiment by using information on the power of the first reflected light R1 and information on the power of the second reflected light R2, received from the imaging element unit 13.

As a result, the heat treatment apparatus 24 uses the imaging element unit 13 in the case where the optical intensity of the reflected laser light L exceeds the allowable threshold of the optical intensity of the reflected laser light L detectable by the detection unit 9. The use of this imaging element unit 13 enables the heat treatment apparatus 24 to detect the temperature state of the laser-irradiated portion without damaging the detection unit 9. In addition, the simple configuration of the heat treatment apparatus 24 can detect, with high accuracy, the temperature state of the laser-irradiated portion without damaging the detection unit 9 even when increasing the rotation speed of the turntable 3 and also increasing the output of the laser light L so as to increase production capacity. It should be noted that the upper limit of the output of the laser light L is set taking into consideration the durability of the semiconductor substrate and the reflecting mirror 7 with respect to the laser light L.

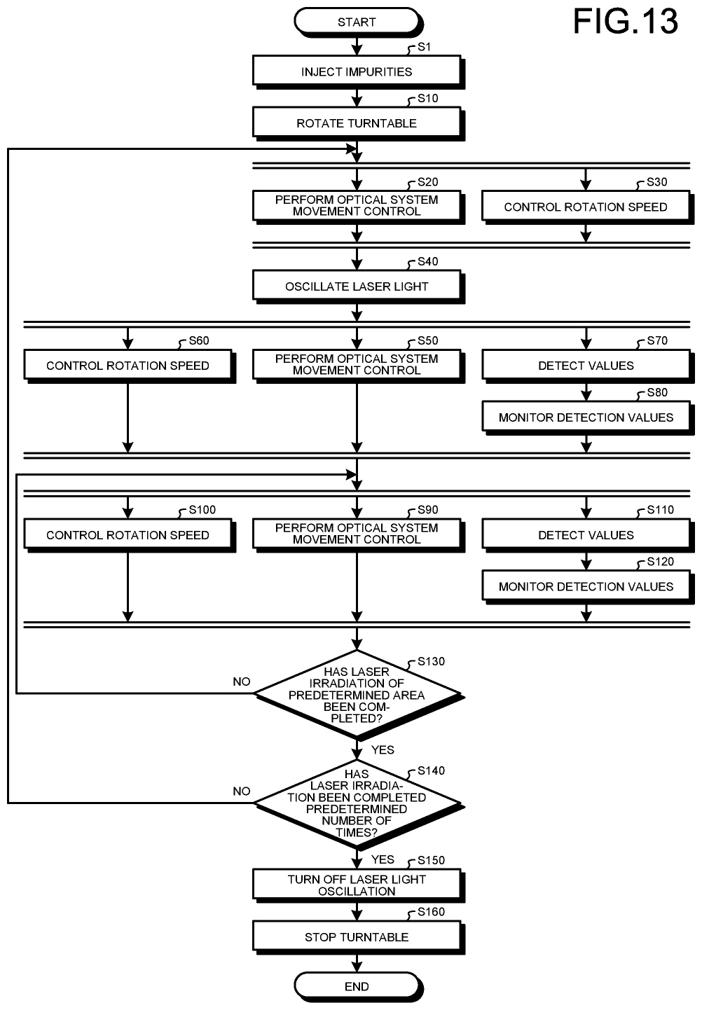

FIG. 13 is a flowchart illustrating a procedure of a method for manufacturing a semiconductor device by use of the heat treatment apparatus 24 according to the fourth embodiment of the present invention. The method for manufacturing a semiconductor device, according to the fourth embodiment, includes a heat treatment method using the heat treatment apparatus 24 according to the fourth embodiment. The method for manufacturing a semiconductor device, according to the fourth embodiment, includes an injection step, an irradiation step, a detection step, and a determination step. In the injection step, impurities are injected into a semiconductor substrate that is an irradiation target to be irradiated with laser light. The semiconductor substrate is used for manufacturing a semiconductor device. In the irradiation step, the semiconductor substrate having the impurities injected thereinto is irradiated with the laser light L. In the detection step, the power of the laser light L reflected from the surface of the semiconductor substrate is detected. In the determination step, the presence or absence of a change in the surface temperature of an area irradiated with the laser light L on the semiconductor substrate is determined on the basis of the detection value of the detected power of the reflected light.

That is, in step S1, impurities are injected into a semiconductor substrate that is the irradiation target 31. Next, heat treatment of the semiconductor substrate having the impurities injected thereinto is performed using the heat treatment apparatus 24. As illustrated in FIG. 13, the procedure of the heat treatment of the semiconductor substrate is basically the same as the heat treatment operation of the heat treatment apparatus 21 according to the first embodiment.

The above-described injection step can be performed in step S1. The irradiation step can be performed in steps S10 to S60, step S90, and step S100. The detection step can be performed in steps S70 and S110. The determination step can be performed in steps S80 and S120.

It should be noted that, in the heat treatment apparatus 24 according to the fourth embodiment, the power of the first reflected light R1 and the power of the second reflected light R2 are obtained by the imaging element unit 13 as described above in the detection steps of steps S70 and S110.

In addition, the irradiation target 31 is not limited to a semiconductor substrate. Furthermore, heat treatment to be performed on a semiconductor substrate that is the irradiation target 31 is not limited to the heat treatment performed using the heat treatment apparatus 24 according to the fourth embodiment. The heat treatment apparatus 21 according to the first embodiment, the heat treatment apparatus 22 according to the second embodiment, and the heat treatment apparatus 23 according to the third embodiment, described above, may be used to perform heat treatment on a semiconductor substrate that is the irradiation target 31.

As described above, in addition to the effect that can be achieved by the heat treatment apparatus 21 according to the first embodiment, the heat treatment apparatus 24 according to the fourth embodiment can also achieve an effect of improving production capacity by increasing the rotation speed of the turntable 3 and increasing the output of the laser light L.

In addition, the detection unit 9 directly measures reflected light. For this reason, each component of the heat treatment apparatus is finely adjusted to such a position that “the angle of incidence of the laser light L on the irradiation target 31=the angle of reflection of the laser light L from the irradiation target 31”.

Meanwhile, the imaging element unit 13 has a high degree of freedom in location as it is only required that the imaging element unit 13 be disposed at a position at which the imaging element unit 13 can detect diffusely reflected light from the irradiation surface on the turntable 3. As a result, the heat treatment apparatus 24 according to the fourth embodiment has an effect of increasing the degree of freedom in configuration for detecting the reflected laser light L.

It should be noted that although the heat treatment apparatus 21 according to the first embodiment with the imaging element unit 13 added has been described above, the imaging element unit 13 may be added to the heat treatment apparatus 22 according to the second embodiment or the heat treatment apparatus 23 according to the third embodiment. Even in the case where the imaging element unit 13 is added to the heat treatment apparatus 22 according to the second embodiment and the case where the imaging element unit 13 is added to the heat treatment apparatus 23 according to the third embodiment, provision of the above-described imaging element unit 13 achieves an effect of increasing production capacity and increasing the degree of freedom in configuration for detecting the reflected laser light L.

The configuration illustrated in each of the above embodiments illustrates an example of the subject matter of the present invention, and it is possible to combine the configuration with another technique that is publicly known, and is also possible to make omissions and changes to part of the configuration without departing from the gist of the present invention.

### REFERENCE SIGNS LIST

1 laser oscillation unit; 2 optical system; 2a collimation lens; 2b objective lens; 3 turntable; 3a base; 3b support shaft; 3c in-plane center; 4 optical system moving unit; 5 first control unit; 6 laser output measuring unit; 7 reflecting mirror; 8 optical fiber; 9 detection unit; 10 determination unit; 11 second control unit; 12 attenuation filter; 13 imaging element unit; 21, 22, 23, 24 heat treatment apparatus; 31 irradiation target; 101 processor; 102 memory; L laser light; R1 first reflected light; R2 second reflected light.

1. A heat treatment apparatus comprising:
a laser oscillator to oscillate laser light;
a stage to hold an irradiation target to be irradiated with the laser light;
an optical guide to guide the laser light oscillated by the laser oscillator to the irradiation target;
a mover to relatively change a positional relationship between the optical guide and the irradiation target;
a detector to detect power of first reflected light that is the laser light reflected from a surface of the irradiation target; and
a determiner to, on a basis of a detection value of the power of the first reflected light detected by the detector, determine presence or absence of a change in a surface temperature of an area irradiated with the laser light on the irradiation target.

2. The heat treatment apparatus according to claim 1, wherein
the determiner calculates the surface temperature of the area irradiated with the laser light on the irradiation target, on the basis of: the detection value of the power of the first reflected light detected by the detector; and correlation data showing a correlation between the surface temperature of the irradiation target and a reflectance of the laser light on the surface of the irradiation target.

3. The heat treatment apparatus according to claim 2, further comprising:
a reflecting mirror provided on the stage,
wherein the detector detects power of second reflected light that is the laser light reflected from a surface of the reflecting mirror, and
the determiner calculates the surface temperature of the area irradiated with the laser light on the irradiation target, on the basis of: a detection value of the power of the second reflected light detected by the detector; a reflectance of the laser light on the surface of the reflecting mirror; the detection value of the power of the first reflected light detected by the detector; and the correlation data.

4. The heat treatment apparatus according to claim 1, further comprising:
a controller to control output of the laser light oscillated by the laser oscillator, on the basis of the detection value of the power of the first reflected light detected by the detector.

5. The heat treatment apparatus according to claim 1, further comprising:
an attenuation filter to attenuate an optical intensity of the laser light incident on the detector.

6. The heat treatment apparatus according to claim 1, wherein
the detector detects the power of the first reflected light by using diffusely reflected light caused by diffuse reflection of the laser light from the surface of the irradiation target.

7. A heat treatment method comprising:
applying laser light to an irradiation target that is to be irradiated with the laser light;
detecting power of first reflected light that is the laser light reflected from a surface of the irradiation target; and
on a basis of a detection value of the detected power of the first reflected light, determining presence or absence of a change in a surface temperature of an area irradiated with the laser light on the irradiation target.

8. The heat treatment method according to claim 7, wherein
the determination of the presence or absence of the change in the surface temperature of the area includes calculating the surface temperature of the area irradiated with the laser light on the irradiation target, on the basis of: the detected value of the power of the first reflected light; and
correlation data showing a correlation between the surface temperature of the irradiation target and a reflectance of the laser light on the surface of the irradiation target.

9. The heat treatment method according to claim 8, further comprising
detecting power of second reflected light that is the laser light reflected from a surface of a reflecting mirror provided on a stage that holds the irradiation target, wherein
the determination of the presence or absence of the change in the surface temperature of the area includes calculating the surface temperature of the area irradiated with the laser light on the irradiation target, on the basis of: a detected value of the power of the second reflected light; a reflectance of the laser light on the surface of the reflecting mirror; the detected value of the power of the first reflected light; and the correlation data.

10. A method for manufacturing a semiconductor device, comprising:
injecting impurities into a semiconductor substrate;
irradiating the semiconductor substrate with laser light, the semiconductor having the impurities injected thereinto;
detecting power of first reflected light that is the laser light reflected from a surface of the semiconductor substrate; and
on a basis of a detection value of the detected power of the first reflected light, determining presence or absence of a change in a surface temperature of an area irradiated with the laser light on the semiconductor substrate.

11. The method for manufacturing a semiconductor device, according to claim 10, wherein
the determination of the presence or absence of the change in the surface temperature of the area includes calculating the surface temperature of the area irradiated with the laser light on the semiconductor substrate, on the basis of: the detected value of the power of the first reflected light; and correlation data showing a correlation between the surface temperature of the semiconductor substrate and a reflectance of the laser light on the surface of the semiconductor substrate.

12. The method for manufacturing a semiconductor device, according to claim 11, further comprising
detecting power of second reflected light that is the laser light reflected from a surface of a reflecting mirror provided on a stage that holds the semiconductor substrate, wherein
the determination of the presence or absence of the change in the surface temperature of the area includes calculating the surface temperature of the area irradiated with the laser light on the semiconductor substrate, on the basis of: a detected value of the power of the second reflected light; a reflectance of the laser light on the surface of the reflecting mirror; the detected value of the power of the first reflected light; and the correlation data.
